(19) United States
(12) Patent Application Publication
(10) Pub. No.: US 2026/0242953 A1
(43) Pub. Date: Aug. 20, 2026

(54) SUBSTRATE PROCESSING APPARATUS, SUBSTRATE PROCESSING METHOD, METHOD OF MANUFACTURING SEMICONDUCTOR DEVICE, AND RECORDING MEDIUM

(71) Applicant: Kokusai Electric Corporation, Tokyo (JP)

(72) Inventor: Kaoru YAMAMOTO, Toyama-shi (JP)

(73) Assignee: Kokusai Electric Corporation, Tokyo (JP)

(21) Appl. No.: 19/644,128

(22) Filed: Apr. 10, 2026

Related U.S. Application Data
(63) Continuation of application No. PCT/JP2024/001822, filed on Jan. 23, 2024.

(51) Int. Cl. C23C 16/46; C23C 16/52; H10P 72/00

(52) U.S. Cl. CPC C23C 16/466; C23C 16/52; H10P 72/0434; H10P 72/0454

(57) ABSTRACT

A technique improves productivity by shortening a heating time of a substrate. The a technique includes: a process chamber in which a substrate is heated; a container in which an unprocessed substrate to be loaded into the process chamber or a processed substrate unloaded from the process chamber is mounted; a supplier that supplies a fluid for heating the unprocessed substrate mounted in the container or cooling the processed substrate; a discharger that discharges the fluid from the container; an accumulator in which the fluid heated by cooling the processed substrate is accumulated; and a controller capable of performing control so as to supply the fluid accumulated in the accumulator to the container to heat the unprocessed substrate.

### CROSS-REFERENCE TO RELATED APPLICATION

This application is a Bypass Continuation Application of PCT International Application No. PCT/JP2024/001822, filed on January 23, 2024, the entire contents of which are incorporated herein by reference.

### BACKGROUND

### FIELD

The present disclosure relates to a substrate processing apparatus, a substrate processing method, a method of manufacturing a semiconductor device, and a recording medium.

### DESCRIPTION OF THE RELATED ART

For example, JP 2023-044818 A discloses a substrate processing apparatus that provides a technique including: a process chamber in which a substrate is processed; a process gas supplier that supplies a process gas to the process chamber; a transfer chamber communicable with the process chamber; a first inert gas supplier that supplies an inert gas to the transfer chamber; a first exhauster that discharges an atmosphere from the transfer chamber; and a second inert gas supplier that supplies the inert gas discharged by the first exhauster to the process chamber or a downstream portion of the process chamber.

### SUMMARY

According to the present disclosure provides a technique for improving productivity by shortening a heating time of a substrate.

According to one aspect, there is provided a technique including: a process chamber in which a substrate is heated; a container in which an unprocessed substrate to be loaded into the process chamber or a processed substrate unloaded from the process chamber is mounted; a supplier that supplies a fluid for heating the unprocessed substrate mounted in the container or cooling the processed substrate; a discharger that discharges the fluid from the container; an accumulator in which the fluid heated by cooling the processed substrate is accumulated; and a controller capable of performing control so as to supply the fluid accumulated in the accumulator to the container to heat the unprocessed substrate.

### BRIEF DESCRIPTION OF THE DRAWINGS

FIG. 1 is an overall schematic diagram of a substrate processing apparatus used in an embodiment of the present disclosure.

FIG. 2 is a side cross-sectional view of the substrate processing apparatus used in the embodiment of the present disclosure.

FIG. 3 is a block diagram of an outline of a controller used in the embodiment of the present disclosure.

FIG. 4 is an example of a screen displayed on a display used in the embodiment of the present disclosure.

FIG. 5 is a schematic diagram of a preheating cooling system used in the embodiment of the present disclosure.

FIG. 6 is a schematic enlarged diagram of an accumulator in FIG. 5.

FIG. 7 is a flowchart illustrating a step of supplying an inert gas to an unprocessed substrate to heat the unprocessed substrate among substrate processing steps according to the embodiment of the present disclosure.

FIG. 8 is a flowchart illustrating a step of supplying an inert gas to a processed substrate to cool the processed substrate among the substrate processing steps according to the embodiment of the present disclosure.

### DETAILED DESCRIPTION

Hereinafter, an embodiment of the present disclosure will be described with reference to the drawings.

A substrate processing apparatus exemplified in the following description is used in a semiconductor device manufacturing process, and is configured to perform predetermined process processing on a substrate to be processed. The substrate to be processed is, for example, a wafer (hereinafter, simply referred to as a “substrate”) serving as a semiconductor substrate in which a semiconductor device is built. Note that, in the present specification, in some cases, the term “substrate” means “a substrate itself” or means “a laminate (aggregate) of a substrate and a predetermined layer or film formed on a surface of the substrate” (that is, a substrate and a predetermined layer or film formed on a surface of the substrate are collectively referred to as a substrate). In the present specification, in some cases, the term “surface of a substrate” means “a surface (exposed face) of a substrate itself” or means “a surface of a predetermined layer or film formed on a substrate, that is, an outermost surface of a substrate serving as a laminate”.

Examples of the predetermined process processing (hereinafter, also simply referred to as “processing”) performed on a substrate include oxidizing processing, diffusing processing, annealing processing, etching processing, pre-cleaning processing, chamber cleaning processing, and film forming processing. In the present embodiment, in particular, a case where film forming processing is performed will be exemplified.

In addition, a processing temperature in the present specification means a temperature of a substrate 200 or a temperature in a process chamber 202, and a processing pressure means a pressure in the process chamber 202. In addition, a processing time means a time during which the processing is continued. The same applies to the following description.

### Configuration

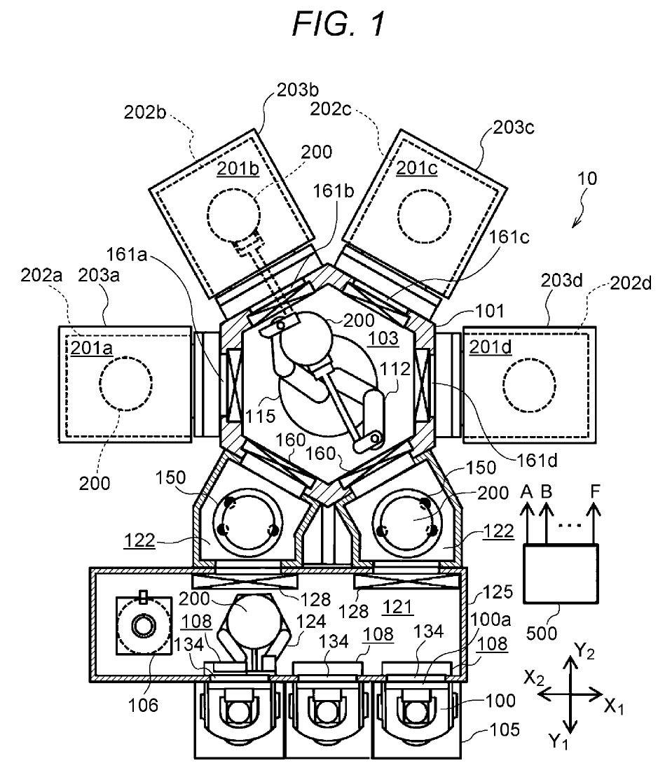

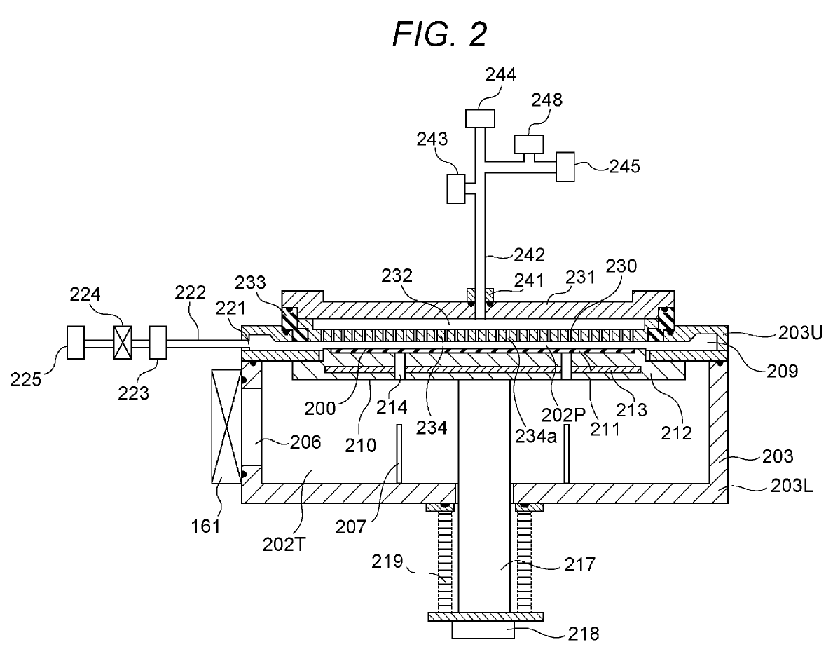

An overall configuration of a substrate processing apparatus 10 according to the embodiment of the present disclosure will be described with reference to FIGS. 1 and 2. FIG. 1 is a transverse cross-sectional view illustrating an overall configuration example of the substrate processing apparatus 10 according to the embodiment. FIG. 2 is a longitudinal cross-sectional view illustrating an overall configuration example of the substrate processing apparatus 10 according to the embodiment. Note that the drawings used in the following description are all schematic, and a dimensional relationship between elements, a ratio between elements, and the like illustrated in the drawings do not necessarily coincide with actual ones. In addition, a dimensional relationship between elements, a ratio between elements, and the like do not necessarily coincide among a plurality of drawings.

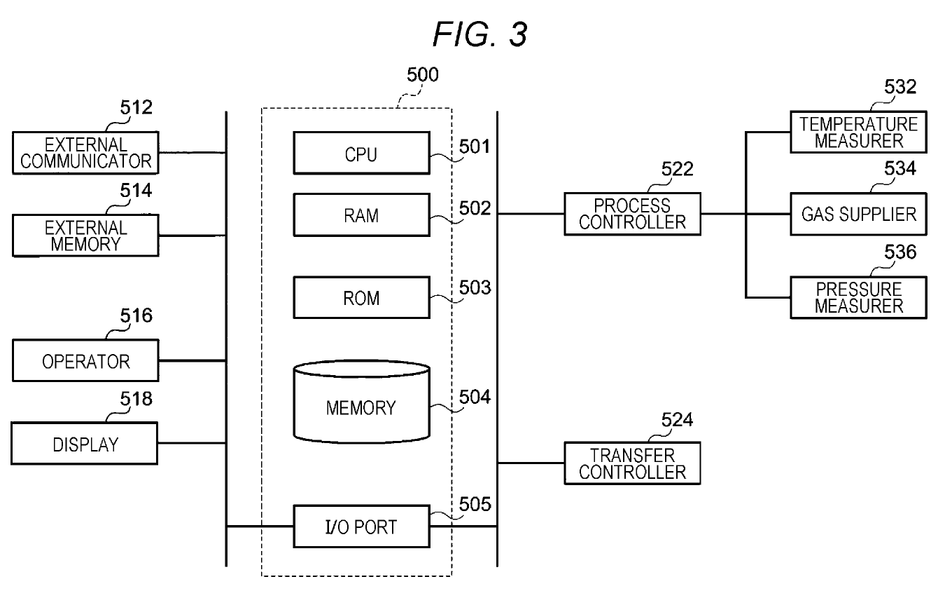

As illustrated in FIGS. 1 and 2, the substrate processing apparatus 10 of the present embodiment includes a plurality of process modules 201a, 201b, 201c, and 201d that process a substrate 200, a vacuum transfer chamber 103 that transfers the substrate 200 under vacuum pressure, a load lock chamber 122 that is a container in which the substrate 200 is mounted by switching between atmospheric pressure and vacuum pressure, an atmospheric transfer chamber 121 that transfers the substrate 200 under atmospheric pressure, a display 518 (see FIG. 3) that displays a status of the substrate processing apparatus 10, and a controller 500 that can control the substrate processing apparatus 10. The substrate processing apparatus 10 according to the present embodiment is a so-called cluster type substrate processing apparatus including a plurality of process modules 201a to 201d around the vacuum transfer chamber 103.

Each of these configurations will be specifically described below. Note that, in the following description, an X1 direction is the right, an X2 direction is the left, a Y1 direction is the front, and a Y2 direction is the rear as for the front, rear, left, and right.

### Process module

First, a detailed configuration of each of the process modules 201a to 201d will be described. The process modules 201a to 201d each function as the single wafer type substrate processing apparatus 10, and have configurations similar to each other.

Here, a specific configuration of one of the process modules 201a to 201d will be described as an example. One of the process modules 201a to 201d will be taken as an example. Therefore, in the following description, the process modules 201a to 201d will be simply described as “process module 201”, cold wall type process containers 203a to 203d constituting the process modules 201a to 201d, respectively, will be simply described as “process container 203”, the process chambers 202a to 202d formed in the process containers 203a to 203d, respectively, will be simply described as “process chamber 202”, and gate valves 161a to 161d corresponding to the process modules 201a to 201d, respectively, will be simply described as “gate valve 161”.

The process module 201 includes the process container 203, a source gas supply system 243, a reactant gas supply system 244, a purge gas supply system 245, a cleaning gas supply system 248, and a gas exhaust system.

### Process container

As described above, the process module 201 is constituted by the cold wall type process container 203. The process container 203 is made of a metal material such as aluminum (Al) or stainless steel (SUS), for example, as a flat sealed container having a circular cross section. The process container 203 includes an upper container 203U and a lower container 203L.

The process chamber 202 is formed in the process container 203. The process chamber 202 includes a process space 202P which is located on an upper side of the process chamber 202 (in a space above a substrate mounting table 212 described later) and in which the substrate 200 such as a wafer is processed, and a transfer space 202T which is a space surrounded by the lower container 203L on a lower side of the process chamber 202.

Near an outer peripheral edge in the upper container 203U, an exhaust buffer chamber 209 is disposed. The exhaust buffer chamber 209 functions as a buffer space when a gas in the process chamber 202 is discharged toward a lateral periphery. Therefore, the exhaust buffer chamber 209 has a space formed so as to surround a lateral outer periphery of the process chamber 202. That is, the exhaust buffer chamber 209 has a space formed in a ring shape (annular shape) in plan view on an outer peripheral side of the process chamber 202.

A side surface of the lower container 203L, that is, one of walls constituting the process container 203 has a substrate loading/unloading port 206 adjacent to the gate valve 161. The substrate 200 is loaded into the transfer space 202T via the substrate loading/unloading port 206. A bottom of the lower container 203L has a plurality of lift pins 207.

### Substrate support

In the process chamber 202, a substrate support (susceptor) 210 that supports the substrate 200 is disposed. The substrate support 210 mainly includes a substrate mounting surface 211 on which the substrate 200 is mounted, a substrate mounting table 212 having the substrate mounting surface 211 on a surface thereof, and a heater 213 serving as a heating source included in the substrate mounting table 212. In the substrate mounting table 212, through-holes 214 through which the lift pins 207 pass are formed at positions corresponding to the lift pins 207, respectively.

The substrate mounting table 212 is supported by a shaft 217. The shaft 217 passes through a bottom of the process container 203, and is further connected to a lifting mechanism 218 outside the process container 203. The lifting mechanism 218 is caused to operate to raise and lower the shaft 217 and the substrate mounting table 212, whereby the substrate mounting table 212 can raise and lower the substrate 200 mounted on the substrate mounting surface 211. Note that a periphery of a lower end of the shaft 217 is covered with bellows 219, and the inside of the process container 203 is airtightly held.

The substrate mounting table 212 is lowered to a position (substrate transfer position) where the substrate mounting surface 211 faces the substrate loading/unloading port 206 at the time of transferring the substrate 200, and is raised until the substrate 200 reaches a processing position (substrate processing position) in the process space 202P at the time of processing the substrate 200.

Specifically, when the substrate mounting table 212 is lowered to the substrate transfer position, an upper end of the lift pin 207 protrudes from an upper surface of the substrate mounting surface 211, and the lift pin 207 supports the substrate 200 from below. When the substrate mounting table 212 is raised to the substrate processing position, the lift pin 207 is buried into the upper surface of the substrate mounting surface 211, and the substrate mounting surface 211 supports the substrate 200 from below.

### Shower head

Above the process space 202P (on an upstream side in a gas supply direction), a shower head 230 serving as a gas dispersion mechanism is disposed. A lid 231 of the shower head 230 has a gas introduction port 241. The gas introduction port 241 is configured such that a gas supply system described later communicates therewith. A gas introduced from the gas introduction port 241 is supplied to a buffer space 232 of the shower head 230.

Between the lid 231 and the upper container 203U, an insulating block 233 is disposed to insulate the lid 231 and the upper container 203U from each other.

The shower head 230 includes a dispersion plate 234 for dispersing a gas supplied from a gas supply system via the gas introduction port 241. An upstream side of the dispersion plate 234 is the buffer space 232, and a downstream side thereof is the process space 202P. The dispersion plate 234 has a plurality of through-holes 234a. The dispersion plate 234 is disposed so as to face the substrate mounting surface 211.

### Gas supply system

A common gas supply pipe 242 is connected to the lid 231 of the shower head 230 so as to communicate with the gas introduction port 241. The common gas supply pipe 242 communicates with the buffer space 232 in the shower head 230 via the gas introduction port 241. To the common gas supply pipe 242, a first gas supply system 243, a second gas supply system 244, and a third gas supply system 245 are connected.

Among these, from a source gas supply system (source gas supplier) which is the first gas supply system 243, a source gas which is one of process gases is mainly supplied, and from a reactant gas supply system (reactant gas supplier) which is the second gas supply system 244, a reactant gas which is another one of the process gases is mainly supplied. From a purge gas supply system (purge gas supplier) which is the third gas supply system 245, an inert gas serving as a purge gas is supplied when the substrate 200 is processed, and from a cleaning gas supply system (cleaning gas supplier) which is a fourth gas supply system 248, a cleaning gas is mainly supplied via the purge gas supply system when the shower head 230 and the process chamber 202 are cleaned. Note that as for a gas supplied from a gas supply system, the source gas may be referred to as a first gas, the reactant gas may be referred to as a second gas, the inert gas may be referred to as a third gas, and the cleaning gas may be referred to as a fourth gas. In addition, the gas supply systems may be collectively referred to as a gas supplier.

### Gas exhaust system

The process container 203 includes an exhaust system 223 that discharges an atmosphere of the process chamber 202 via an exhaust port 221 formed on an upper surface or a lateral of the exhaust buffer chamber 209. In addition, the exhaust system 223 includes an auto pressure controller (APC) (not illustrated), and controls a pressure in the process container 203 according to an instruction from the controller 500 described later.

### Atmospheric transfer chamber

The atmospheric transfer chamber 121 is connected to a front side of the load lock chamber 122 via a gate valve 128. The atmospheric transfer chamber 121 is used under substantially atmospheric pressure.

In the atmospheric transfer chamber 121, an atmospheric transfer robot 124 that transfers the substrate 200 is disposed. The atmospheric transfer robot 124 is configured to be raised and lowered or movable in a left-right direction (see FIG. 1).

On a left side of the atmospheric transfer chamber 121, a device (hereinafter, referred to as a “pre-aligner”) 106 that aligns a notch or an orientation flat formed on the substrate 200 is disposed (see FIG. 1).

### IO stage

On a front side of a housing 125 of the atmospheric transfer chamber 121, a substrate loading/unloading port 134 for loading/unloading the substrate 200 into/from the atmospheric transfer chamber 121 and a pod opener 108 are disposed. On a side opposite to the pod opener 108 across the substrate loading/unloading port 134, that is, on an outer side of the housing 125, an IO stage 105 is disposed.

On the IO stage 105, a plurality of front opening unified pods (FOUP, hereinafter referred to as “pod”) 100 that stores a plurality of the substrates 200 is mounted. The pod 100 is used as a carrier that transfers the substrate 200 such as a silicon (Si) substrate. The pod 100 is configured to store a plurality of unprocessed substrates 200 and a plurality of processed substrates 200 in a horizontal posture therein. The pod 100 is supplied to and discharged from the IO stage 105 by an in-process transfer device (RGV) (not illustrated).

The pod 100 on the IO stage 105 is opened and closed by the pod opener 108. The pod opener 108 includes a mechanism for opening and closing a cap (not illustrated) of the pod 100. The pod opener 108 opens and closes a cap (not illustrated) of the pod 100 mounted on the IO stage 105 to open and close a substrate loading/unloading port, thereby making it possible to load/unload the substrate 200 into/from the pod 100.

### Vacuum transfer chamber

The vacuum transfer chamber 103 functions as a transfer chamber serving as a transfer space in which the substrate 200 is transferred under negative pressure. A housing 101 constituting the vacuum transfer chamber 103 is formed in a hexagonal shape in plan view. To sides of the hexagon, the load lock chambers 122 and the process modules 201a to 201d are connected via gate valves 160 and 161a to 161d, respectively.

To remaining four side walls to which the load lock chamber 122 is not connected among the six side walls of the housing 101 constituting the vacuum transfer chamber 103, the process modules 201a to 201d that perform desired processing on the substrate 200 are connected via the gate valves 161a to 161d so as to be located radially around the vacuum transfer chamber 103, respectively. The process modules 201a to 201d are constituted by the cold wall type process containers 203a to 203d, and process chambers 202a to 202d are formed therein, respectively. In each of the process chambers 202a to 202d, the substrate 200 is processed as one step of a semiconductor or semiconductor device manufacturing process. Examples of the processing performed in each of the process chambers 202a to 202d include various types of substrate processing such as processing of forming a thin film on a substrate, processing of oxidizing, nitriding, carbonizing, or the like a substrate surface, formation of a film formed of a silicide, a metal, or the like, processing of etching a substrate surface, and reflow processing.

At a substantially central portion of the vacuum transfer chamber 103, a vacuum transfer robot 112 serving as a transfer robot that transfers the substrate 200 under negative pressure is disposed with a flange 115 as a base. The vacuum transfer robot 112 is configured to be raised and lowered by an elevator 116 and the flange 115 while maintaining airtightness of the vacuum transfer chamber 103 (see FIG. 1).

### Load lock chamber

To two side walls located on a front side among the six side walls of the housing 101 constituting the vacuum transfer chamber 103, the two load lock chambers 122 which are examples of the container in the present embodiment are connected via the gate valves 160. A substrate mounting table 150 for loading and unloading is disposed in each of the load lock chambers 122. Note that each of the load lock chambers 122 is configured to be able to withstand negative pressure. Note that the two load lock chambers 122 may be used for loading and unloading, respectively.

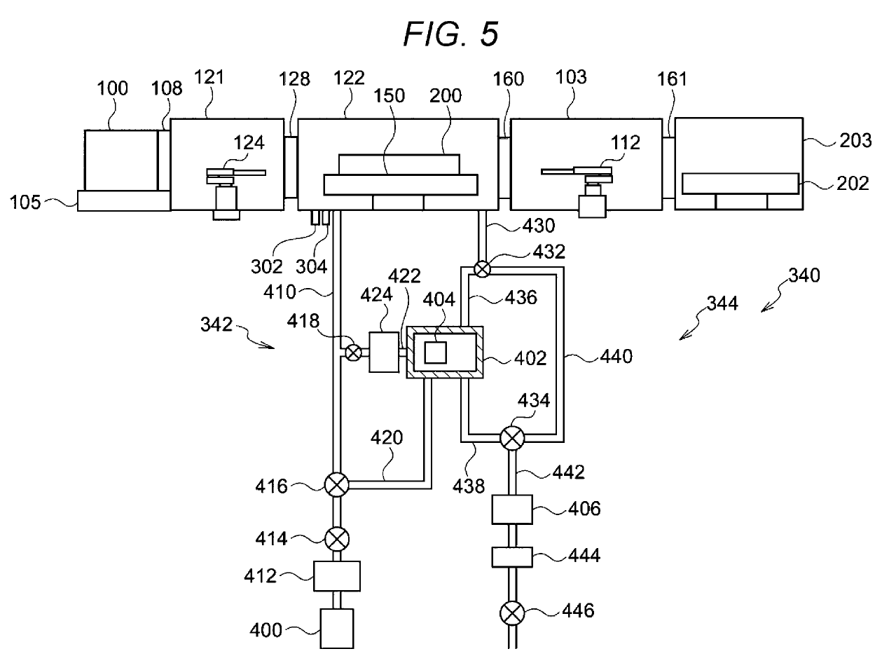

As illustrated in FIG. 5 described later, the load lock chamber 122 has a temperature sensor 302 and a pressure sensor 304. The temperature sensor 302 measures a temperature in the load lock chamber 122 and transmits the measured value to a temperature measurer 532 described later. The pressure sensor 304 measures a pressure in the load lock chamber 122 and transmits the measured value to a pressure measurer 536 described later. A preheating cooling system is connected to the load lock chamber 122. Note that the preheating cooling system will be described later.

The inside of the load lock chamber 122 can be switched to an atmospheric pressure state or a vacuum pressure state, and for example, when the unprocessed substrate 200 is loaded into the load lock chamber 122 from the atmospheric transfer chamber 121 or the processed substrate 200 is unloaded from the load lock chamber 122 to the atmospheric transfer chamber 121, the inside of the load lock chamber 122 is switched to the atmospheric pressure state. When the processed substrate 200 is loaded into the load lock chamber 122 from the vacuum transfer chamber 103 or the unprocessed substrate 200 is unloaded from the load lock chamber 122 to the vacuum transfer chamber 103, the inside of the load lock chamber 122 is switched to the vacuum pressure state.

### Controller

The controller 500 is a component that controls operation of each unit constituting the substrate processing apparatus 10. As illustrated in FIG. 3, the controller 500 includes a central processing unit (CPU) 501 which is an example of a processor and a random access memory (RAM) 502 used as a temporary work area of the CPU 501. In addition, the controller 500 includes a read only memory (ROM) 503 that stores a control program for causing the CPU 501 to function as the controller 500, a memory 504 that stores an execution result of the program, and an I/O port 505. The CPU 501, the RAM 502, the memory 504, and the I/O port 505 are connected to each other via a bus (not illustrated).

As described above, a dedicated processor and memory for executing each piece of processing are allocated to the controller 500. The CPU 501 reads a control program from the ROM 503 and executes control of the entire substrate processing apparatus 10, to be performed by the controller 500. That is, the controller 500 in the present embodiment is also an example of a computer.

The memory 504 is an example of a memory device in which stored information is maintained even when power supplied to each unit is cut off, and for example, a semiconductor memory is used, but a hard disk may be used.

In addition, as illustrated in FIG. 3, a process controller 522 and a transfer controller 524 are connected to the I/O port 505.

The process controller 522 is a control device that performs control such that the substrate processing apparatus 10 executes a processing procedure of the substrate 200. Specifically, the process controller 522 is connected to the temperature measurer 532, the gas supplier 534, and the pressure measurer 536.

As an example, the temperature measurer 532 is a device that is connected to a temperature sensor (not illustrated) disposed in the process chamber 202 or the like or the temperature sensor 302 disposed in the load lock chamber 122, measures a temperature of an internal space of the configuration or a temperature of the substrate 200, and transmits the measurement result to the controller 500.

As an example, the gas supplier 534 is a device that is connected to the above-described processing units and controls supply and stop of various gases. The gas supplier 534 is also a device that controls a gas supplied to the process chamber 202 or the load lock chamber 122 by controlling various valves and the like included in a preheating cooling system described later.

As an example, the pressure measurer 536 is a device that is connected to a pressure sensor (not illustrated) disposed in the process chamber 202 or the like or the pressure sensor 304 disposed in the load lock chamber 122, measures a pressure of an internal space of the configuration, and transmits the measurement result to the controller 500.

The transfer controller 524 is a control device that is connected to a driving configuration such as the atmospheric transfer robot 124, the vacuum transfer robot 112, or the gate valve 160, and controls drive of the configuration on the basis of an instruction from the controller 500.

In addition, as illustrated in FIG. 3, an external communicator 512, an external memory 514, an operator 516, and the display 518 are connected to the I/O port 505.

The external communicator 512 is connected to a communication line and includes a communication protocol that transmits and receives data to and from an external device (not illustrated) connected to the same communication line. The external communicator 512 performs data communication with an external device according to an instruction from the CPU 501 in the controller 500.

The external memory 514 is a device that is disposed separately from the memory 504 included in the controller 500 and stores various types of data and the like. A specific configuration of the external memory 514 is not particularly limited, but as an example, a memory device connected through a network such as a network attached storage (NAS) or a portable recording medium such as an SD memory card is used.

The operator 516 is a device that receives a worker's instruction and notifies the CPU 501 of the controller 500 of the received instruction, and examples thereof include a button disposed on a housing of the substrate processing apparatus 10 and a pendant board connected to the substrate processing apparatus 10. The display 518 is a display device that displays information of the substrate processing apparatus 10, and examples thereof include a liquid crystal display and an organic electro luminescence (EL) display.

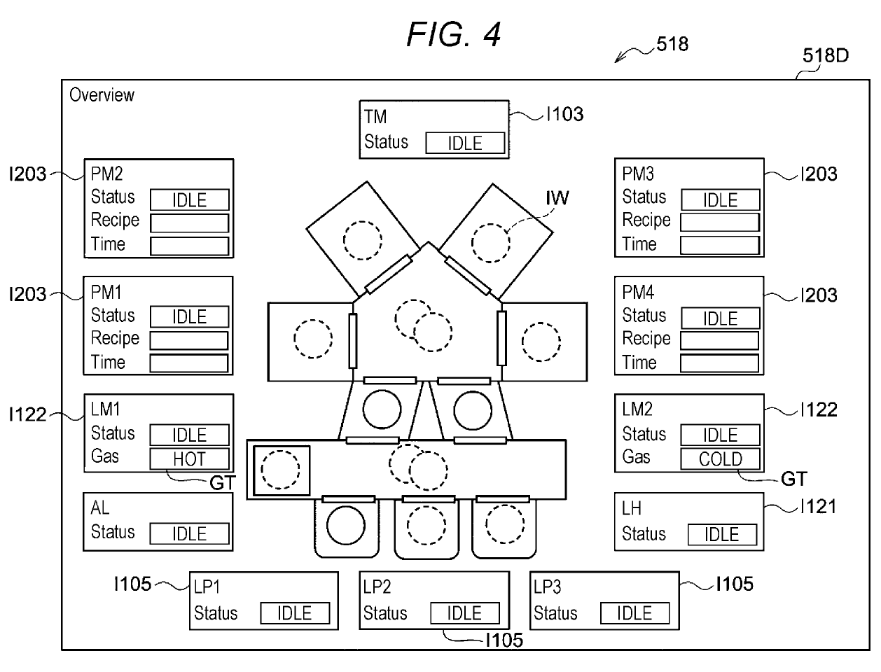

Note that, in the present embodiment, the display 518 and the operator 516 will be described by taking a touch panel that can be operated by a worker touching a screen as illustrated in FIG. 4 described later as an example. In other words, in the present embodiment, the touch panel is a device also serving as the display 518 and the operator 516. A specific description for contents displayed on the touch panel will be described later.

Note that each configuration connected to the I/O port 505 is an example, and a configuration corresponding to the function of the substrate processing apparatus 10 is connected. Note that the configuration represents an execution unit that executes processing under control of a processor such as the CPU 501 or the RAM 502.

### Display

As illustrated in FIG. 4, each configuration of the substrate processing apparatus 10 is schematically displayed on a display screen 518D of the display 518.

More specifically, as illustrated in FIG. 4, on the display screen 518D, icons I105 indicating statuses of the plurality of IO stages 105 and an icon I121 indicating a status of the atmospheric transfer chamber 121 are displayed. Furthermore, on the display screen 518D, icons I122 respectively indicating statuses of the plurality of load lock chambers 122, an icon I103 indicating a status of the vacuum transfer chamber 103, and icons I203 respectively indicating statuses of the plurality of process chambers 202 are displayed. Furthermore, on the display screen 518D, an icon IW indicating the presence or absence of the substrate 200 is displayed.

Note that the “status” referred to in the above description includes not only the presence or absence of other configurations housed in each configuration but also a status such as a step being performed by each configuration and a temperature of a gas supplied to each configuration.

The icon I122 indicating a status of the load lock chamber 122 includes a gas temperature icon GT indicating a temperature of an inert gas supplied to the load lock chamber 122. As an example, when display of the gas temperature icon GT is “HOT”, a high-temperature inert gas is supplied to the load lock chamber 122, and when display of the gas temperature icon GT is “COLD”, a low-temperature inert gas is supplied to the load lock chamber 122.

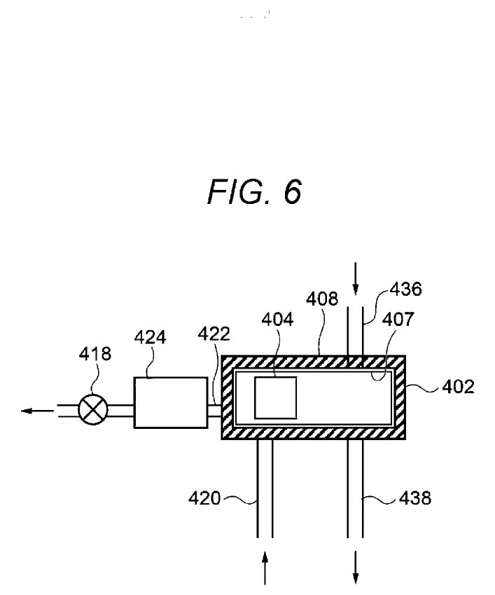

Subsequently, a preheating cooling system 340 according to the present embodiment will be described with reference to FIGS. 5 and 6.

### Preheating cooling system

As illustrated in FIG. 5, the preheating cooling system 340 includes an inert gas supply system 342, an inert gas discharge system 344, and an accumulator 402.

### Inert gas supply system

As illustrated in FIG. 5, the inert gas supply system 342 includes a tank 400, a supply pipe 410, a first on-off valve 414, a first three-way valve 416, a second on-off valve 41 8, a first introduction pipe 420, and a first discharge pipe 422.

The tank 400 stores an inert gas which is an example of a fluid according to the present embodiment. A temperature of the inert gas stored in the tank 400 is, for example, room temperature or a temperature equivalent to that of an environment in which the substrate processing apparatus 10 is disposed. In other words, the temperature of the inert gas stored in the tank 400 is lower than a temperature at which the substrate 200 is processed in the substrate processing apparatus 10. That is, the inert gas in the tank 400 according to the present embodiment is an example of a “cold fluid” in the present embodiment.

The supply pipe 410 is a member that connects the tank 400 and the load lock chamber 122, and causes an inert gas in the tank 400 to flow into the load lock chamber 122. In the supply pipe 410, a mass flow controller (MFC) 412, the first on-off valve 414, and the first three-way valve 416 are disposed in this order from the tank 400 side.

The MFC 412 is a component having a function of adjusting a flow rate and a pressure of an inert gas supplied from the tank 400. The first on-off valve 414 is a component that opens and closes a flow path of the supply pipe 410, and can control a flow of an inert gas supplied from the tank 400 on a downstream side of the MFC 412.

The first three-way valve 416 is a valve disposed downstream of the MFC 412 in the supply pipe 410, and can switch a flow path such that an inert gas flowing through the supply pipe 410 flows to the first introduction pipe 420 as illustrated in FIG. 5.

As illustrated in FIG. 5, the first introduction pipe 420 is connected to the first three-way valve 416 and the accumulator 402, and is a component capable of causing an inert gas to flow from the first three-way valve 416 into the accumulator 402.

The first discharge pipe 422 is a member that connects the supply pipe 410 and the accumulator 402, and can cause an inert gas to flow from the accumulator 402 to the supply pipe 410. In the first discharge pipe 422, a first filter 424 and a second on-off valve 418 are disposed in this order from the accumulator 402 side.

As described later, the first filter 424 is a member that removes impurities contained in an inert gas stored in the accumulator 402. The impurities include, for example, particles generated by processing of the substrate and a residual gas of a process gas. Note that the first filter 424 has such heat resistance that the first filter 424 is not broken even when an inert gas heated to a temperature at which the substrate 200 is processed in the substrate processing apparatus 10 passes through the first filter 424.

The second on-off valve 418 is a component that opens and closes a flow path of the first discharge pipe 422, and can control a flow of an inert gas supplied from the accumulator 402 on a downstream side of the first filter 424.

Note that, in the present embodiment, a flow path of a fluid flowing from the tank 400 to the load lock chamber 122 is switched by operation of the first three-way valve 416 and opening and closing of the second on-off valve 418. In other words, the combination of the first three-way valve 416 and the second on-off valve 418 is an example of a supply source switching valve in the present embodiment.

That is, the inert gas supply system 342 in the present embodiment is an example of a “supplier” in the present embodiment. The MFC 412 and the first on-off valve 414 are examples of a “first supplier” in the present embodiment. Note that the tank 400 may be included in the first supplier. The first filter 424 and the second on-off valve 418 are examples of a “second supplier” in the present embodiment. Note that the accumulator 402 and a heater 404 described later may be included in the second supplier.

Note that the tank 400 in the above description of the configuration is an example of a “fluid supply source” in the present embodiment. In other words, the fluid supply source is not limited to the tank 400 as long as an inert gas can be supplied to the supply pipe 410, and other configurations may be used.

### Inert gas discharge system

As illustrated in FIG. 5, the inert gas discharge system 344 includes a discharge pipe 430, a second three-way valve 432, a third three-way valve 434, a bypass pipe 440, a second introduction pipe 436, a second discharge pipe 438, an exhaust pipe 442, a third on-off valve 446, and a vacuum pump 406.

One end of the discharge pipe 430 is connected to the load lock chamber 122, and can cause a fluid (including air, an inert gas, and a process gas) in the load lock chamber 122 to flow through the discharge pipe 430. The second three-way valve 432 is disposed at the other end of the discharge pipe 430.

The second three-way valve 432 is a component that connects ends of the discharge pipe 430, the second introduction pipe 436, and the bypass pipe 440 and causes a fluid flowing through the discharge pipe 430 to flow through the second introduction pipe 436 or the bypass pipe 440.

The bypass pipe 440 is a member that connects the second three-way valve 432 and the third three-way valve 434, and can cause a fluid to flow from the second three-way valve 432 to the third three-way valve 434.

The second introduction pipe 436 is a member that connects the second three-way valve 432 and the accumulator 402, and can cause an inert gas to flow from the second three-way valve 432 to the accumulator 402.

The second discharge pipe 438 is a member that connects the accumulator 402 and the third three-way valve 434, and can cause an inert gas to flow from the accumulator 402 to the third three-way valve 434.

The third three-way valve 434 is a component that connects ends of the second discharge pipe 438, the bypass pipe 440, and the exhaust pipe 442, and causes a fluid flowing through the second discharge pipe 438 or the bypass pipe 440 to flow through the exhaust pipe 442.

The exhaust pipe 442 is a member that connects the third three-way valve 434 and the third on-off valve 446, and has the vacuum pump 406 and a second filter 444 in this order from the third three-way valve 434 side.

The vacuum pump 406 is a device that sends out a fluid in the exhaust pipe 442 on an upstream side (the third three-way valve 434 side) to a downstream side (the third on-off valve 446 side). That is, in a case where the vacuum pump 406 is operated, a fluid in a pipe body (including the bypass pipe 440, the second discharge pipe 438, the second introduction pipe 420, and the discharge pipe 430) of the exhaust pipe 442 on an upstream side of the vacuum pump 406 is sent out to a downstream side of the vacuum pump 406 (the third three-way valve 434 side).

As described later, the second filter 444 is a member that removes impurities contained in a fluid (including an inert gas) flowing through the exhaust pipe 442. Note that the second filter 444 has such heat resistance that the second filter 444 is not broken even when an inert gas heated to a temperature at which the substrate 200 is processed in the substrate processing apparatus 10 passes through the second filter 444.

The third on-off valve 446 is a component that opens and closes a flow path of the exhaust pipe 442, and can control a flow of a fluid flowing through the exhaust pipe 442 on a downstream side of the second filter 444.

Note that the exhaust pipe 442 is opened to the outside of the substrate processing apparatus 10 on a downstream side of the third on-off valve 446. In other words, a fluid flowing through the exhaust pipe 442 is discharged to an atmospheric space.

Note that, in the present embodiment, a flow path of a fluid flowing from the discharge pipe 430 to the exhaust pipe 442 is switched by operation of the second three-way valve 432 and operation of the third three-way valve 434. That is, a combination of the second three-way valve 432 and the third three-way valve 434 is an example of a discharge destination switching valve in the present embodiment.

Note that the inert gas discharge system 344 in the above-described description of the configuration is an example of a “discharger that discharges a fluid” in the present embodiment. In other words, the discharger that discharges a fluid is not limited to the configuration of the inert gas discharge system 344 described above as long as the discharger can discharge a fluid in the load lock chamber 122, and other configurations may be used. The discharger may include the vacuum pump 406.

### Accumulator

As illustrated in FIGS. 5 and 6, the accumulator 402 is a tank-shaped component including a housing 407 and a heat insulating member 408. The accumulator 402 is connected to the first introduction pipe 420, the second introduction pipe 436, the first discharge pipe 422, and the second discharge pipe 438. That is, the accumulator 402 is a component that stores an inert gas in the housing 407 by the inert gas being poured thereinto by the first introduction pipe 420 and the second introduction pipe 436. The accumulator 402 is a component that sends out the inert gas stored in the housing 407 from the first discharge pipe 422 and the second discharge pipe 438.

Note that, as illustrated in FIG. 6, the housing 407 is surrounded by the heat insulating member 408 which is an example of a heat insulating material in the present embodiment. Therefore, a temperature of the inert gas stored in the accumulator 402 is maintained.

As illustrated in FIGS. 5 and 6, the accumulator 402 in the present embodiment includes the heater 404 therein. The heater 404 is a component that heats an inert gas stored in the accumulator 402, and is, for example, a heater that generates heat when power is supplied from a power supply (not illustrated).

Note that, in the present embodiment, all active members among the components of the preheating cooling system 340 are controlled by the controller 500. In other words, the first on-off valve 414, the first three-way valve 416, the second on-off valve 418, the second three-way valve 432, the third three-way valve 434, the third on-off valve 446, the MFC 412, the vacuum pump 406, and the heater 404 are all controlled by the controller 500 to be able to switch an operation state.

Note that, in the substrate processing apparatus 10 in the present embodiment, the preheating cooling system 340 is disposed for each load lock chamber 122. For example, since the substrate processing apparatus 10 in the present embodiment includes the two load lock chambers 122 as illustrated in FIG. 1, the two preheating cooling systems 340 in total are disposed in the load lock chambers 122, respectively. Note that the tank 400 may be shared by the two preheating cooling systems 340.

Note that, in the inert gas supply system 342 described above, a supply source of an inert gas is not limited to the tank 400. For example, the supply pipe 410 may supply an inert gas by being connected to the purge gas supply system instead of the tank 400.

Next, as one step of the semiconductor manufacturing process, a substrate processing step of processing the substrate 200 using the substrate processing apparatus 10 having the above-described configuration will be described. Note that, in the following description, operation of each unit constituting the substrate processing apparatus 10 is controlled by the controller 500.

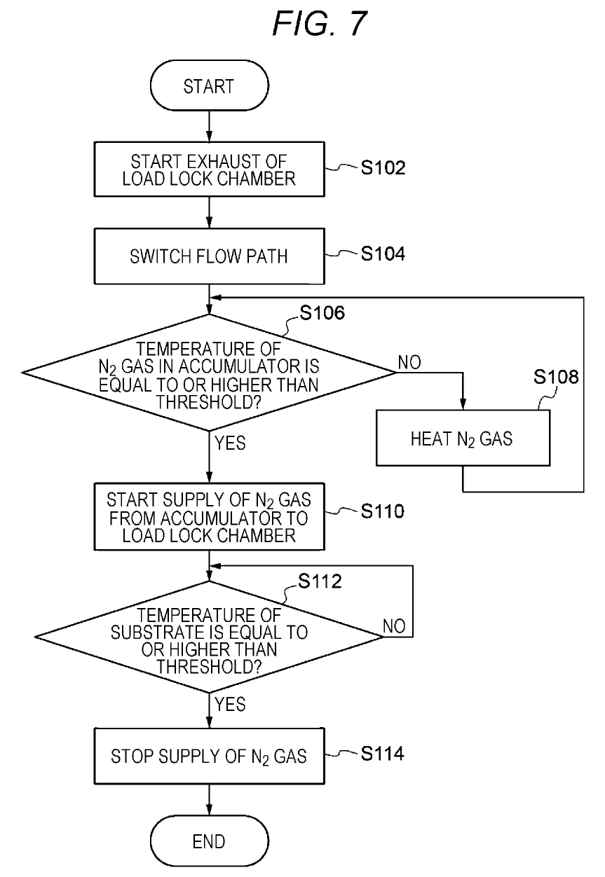

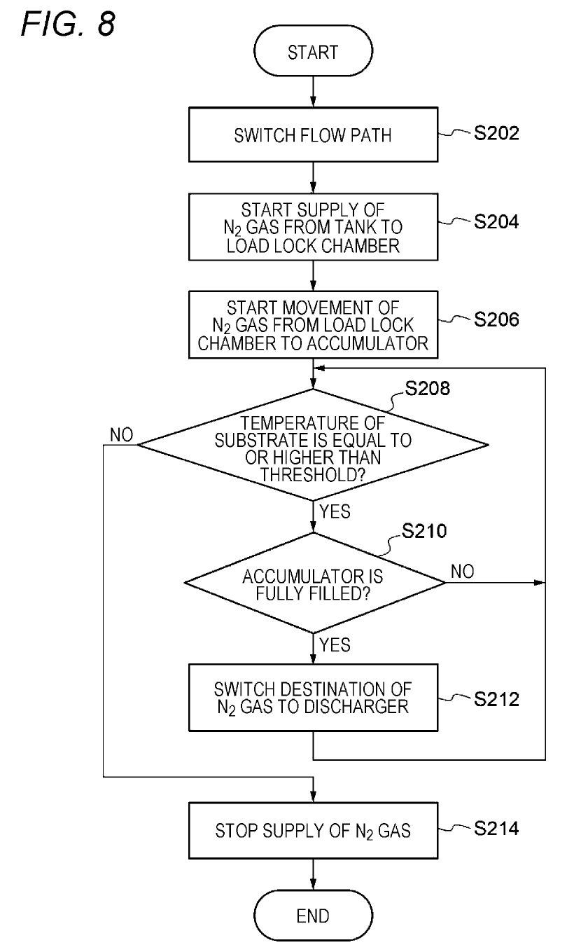

Here, as the substrate processing step, a step of forming a thin film on the substrate 200 will be described with reference to FIGS. 7 and 8. Note that as an inert gas in the present embodiment, a N₂ gas is used as an example.

### Method of manufacturing semiconductor device

A semiconductor manufacturing method according to the present embodiment includes a step of taking out the unprocessed substrate 200 from the pod 100 and transferring the unprocessed substrate 200 to the load lock chamber 122, and a step of preheating the unprocessed substrate 200 in the load lock chamber 122. The semiconductor manufacturing method according to the present embodiment further includes a step of transferring the unprocessed substrate 200 to the process chamber 202, a step of processing the unprocessed substrate 200 in the process chamber 202, and a step of transferring the processed substrate 200 to the load lock chamber 122. The semiconductor manufacturing method according to the present embodiment further includes a step of cooling the processed substrate 200 in the load lock chamber 122, and a step of transferring the processed substrate 200 to an atmospheric transfer chamber 121 and housing the processed substrate 200 in the pod 100. Note that the CPU 501 of the controller 500 reads a program stored in the ROM 503 and executes these steps according to a procedure of the read program.

Note that, in the following procedure, unless otherwise specified, a case where the first unprocessed substrate 200 is processed in production (lot production) in which a plurality of unprocessed substrates 200 are sequentially processed will be described. The second and subsequent unprocessed substrates 200 will be described later.

### Step of taking out unprocessed substrate from pod and transferring unprocessed substrate to load lock chamber

In a step of taking out the unprocessed substrate 200 from the pod 100 and transferring the unprocessed substrate 200 to the load lock chamber 122, the inside of the load lock chamber 122 is switched to the atmospheric pressure in a state where the gate valve 128 and the gate valve 160 are closed. Thereafter, the atmospheric transfer robot 124 takes out the unprocessed substrate 200 from the pod 100 mounted on the IO stage 105. After opening the gate valve 128, the atmospheric transfer robot 124 mounts the taken out unprocessed substrate 200 on the substrate mounting table 150 of the load lock chamber 122. Then, the gate valve 128 of the load lock chamber 122 is closed.

(Step of preheating unprocessed substrate in load lock chamber)

Subsequently, in a step of preheating the unprocessed substrate 200 in the load lock chamber 122, the controller 500 preheats the unprocessed substrate 200. Note that, in the present description, “preheating” refers to work of heating the substrate 200 to a temperature lower than a temperature at which the substrate 200 is processed in the process chamber 202 but higher than an outside air temperature. A procedure executed by the controller 500 will be described with reference to FIG. 7. Note that, at a time when the unprocessed substrate 200 is transferred to the load lock chamber 122 (before step S102), all of the first on-off valve 414, the second on-off valve 418, and the third on-off valve 446 are closed.

First, in step S102, the controller 500 exhausts the load lock chamber 122. More specifically, the controller 500 starts the vacuum pump 406 and controls the third on-off valve 446 to open the third on-off valve 446. The controller 500 controls the second three-way valve 432 to connect the discharge pipe 430 and the bypass pipe 440, and controls the third three-way valve 434 to connect the bypass pipe 440 and the exhaust pipe 442. As a result, the controller 500 discharges a fluid (atmosphere such as atmospheric) in the load lock chamber 122 from the load lock chamber 122 to make the inside of the load lock chamber 122 vacuum (lower pressure than atmospheric pressure). Then, the controller 500 proceeds to step S104.

Next, in step S104, the controller 500 switches a flow path of the inert gas supply system 342. More specifically, the controller 500 controls the first on-off valve 414 to open the first on-off valve 414, and controls the first three-way valve 416 to connect the supply pipe 410 and the first introduction pipe 420 to cause a N₂ gas to flow into the accumulator 402. Then, the controller 500 proceeds to step S106.

Next, in step S106, the controller 500 measures a temperature of the N₂ gas in the accumulator 402 and determines whether the temperature is equal to or higher than a predetermined temperature (threshold). Then, if an affirmative determination is made in step S106, the controller 500 proceeds to step S110. On the other hand, if a negative determination is made in step S106, the controller 500 proceeds to step S108.

Next, in step S108, the controller 500 heats the N₂ gas in the accumulator 402. More specifically, the controller 500 heats the N₂ gas in the accumulator 402 by controlling the heater 404 to generate heat. Then, after a predetermined time has elapsed, the controller 500 proceeds to step S106.

Next, in step S110, the controller 500 starts supply of the N₂ gas from the accumulator 402 to the load lock chamber 122. More specifically, the controller 500 opens the second on-off valve 418 to connect the accumulator 402 and the load lock chamber 122 through the first discharge pipe 422. Since the N₂ gas has been supplied from the tank 400 to the accumulator 402 through the first introduction pipe 420 and a pressure in the accumulator 402 exceeds that in the load lock chamber 122, the N₂ gas in the accumulator 402 flows into the load lock chamber 122. Then, the controller 500 proceeds to step S112.

Next, in step S112, the controller 500 determines whether a temperature of the unprocessed substrate 200 mounted on the substrate mounting table 150 of the load lock chamber 122 is equal to or higher than a predetermined temperature (threshold). Then, if an affirmative determination is made in step S112, the controller 500 proceeds to step S114. On the other hand, if a negative determination is made in step S112, the controller 500 repeats step S112. In other words, the controller 500 causes a N₂ gas to flow from the accumulator 402 to the load lock chamber 122 until the temperature of the unprocessed substrate 200 exceeds the predetermined temperature in step S112.

Next, in step S114, the controller 500 stops the supply of the N₂ gas. More specifically, the controller 500 controls the first on-off valve 414 and the second on-off valve 418 to close the first on-off valve 414 and the second on-off valve 418. As a result, the N₂ gas in the load lock chamber 122 is discharged.

### Step of transferring unprocessed substrate to process chamber

Subsequently, in a step of transferring the unprocessed substrate 200 to the process chamber 202, the controller 500 opens the gate valve 160 of the load lock chamber 122 and operates the vacuum transfer robot 112 to transfer the substrate 200 mounted on the substrate mounting table 150 of the load lock chamber 122 to any one of the process chambers 202. After the substrate 200 is transferred to the process chambers 202, the vacuum transfer robot 112 is retracted to the outside of the process container 203, and the gate valve 161 is closed to seal the inside of the process container 203. Thereafter, the controller 500 raises the substrate mounting table 212 to mount the substrate 200 on a substrate mounting surface formed on the substrate mounting table 212. The substrate mounting table 212 is further raised to raise the substrate 200 to a processing position (substrate processing position) in the process chamber 202.

When the substrate 200 is raised to the substrate processing position, the controller 500 causes the exhaust system 223 to be operated to cause the exhaust buffer chamber 209 and the vacuum pump 224 to communicate with each other. The exhaust system 223 adjusts a conductance of exhaust piping to control an exhaust flow rate of the exhaust buffer chamber 209 by the vacuum pump 224, and maintains a pressure of the process chamber 202 communicating with the exhaust buffer chamber 209 at a predetermined pressure.

### Step of processing unprocessed substrate in process chamber

Subsequently, in a step of processing the unprocessed substrate 200 in the process chamber 202, the controller 500 performs a film formation process on the substrate 200. More specifically, first, the controller 500 supplies power to the heater 213 embedded in the substrate mounting table 212 on which the substrate 200 is mounted, and performs control such that a surface of the substrate 200 has a predetermined processing temperature.

Next, according to a predetermined procedure (recipe), the controller 500 alternately supplies a source gas (first gas) and a reactant gas (second gas) to form a desired film on the substrate 200. Note that supply amounts, supply times, processing times, processing temperatures, and the like of the source gas and the reactant gas are appropriately determined according to a recipe that is a predetermined procedure.

### Step of transferring processed substrate to load lock chamber

Subsequently, in a step of transferring the processed substrate 200 to the load lock chamber 122, the controller 500 transfers the processed substrate 200 from the process chamber 202 to the load lock chamber 122 in a procedure reverse to the above-described step. More specifically, the controller 500 first lowers the substrate mounting table 212 from the substrate processing position to the substrate transfer position. Thereafter, the controller 500 opens the gate valve 160 of the load lock chamber 122 and operates the vacuum transfer robot 112 to transfer the processed substrate 200 from the substrate mounting table 212 to the substrate mounting table 150 of the load lock chamber 122. At this time, when the load lock chamber 122 has an atmospheric pressure, the pressure is switched to a vacuum pressure.

### Step of cooling processed substrate in load lock chamber 122

Subsequently, in a step of cooling the processed substrate 200 in the load lock chamber 122, the controller 500 cools the processed substrate 200. A procedure executed by the controller 500 will be described with reference to FIG. 8. Note that, at a time when the processed substrate 200 is transferred to the load lock chamber 122 (before step S202), all of the first on-off valve 414, the second on-off valve 418, and the third on-off valve 446 are closed.

First, in step S202, the controller 500 switches a flow path of the inert gas supply system 342. More specifically, the controller 500 controls the first three-way valve 416 to release connection between the supply pipe 410 and the first introduction pipe 420, and switches the flow path such that an inert gas flows from the tank 400 to the load lock chamber 122 without passing through the accumulator 402. Then, the controller 500 proceeds to step S204. Here, the inert gas indicates, for example, a N₂ gas. In the present embodiment, the inert gas is referred to as a N₂ gas.

Next, in step S204, the controller 500 starts supply of the N₂ gas from the tank 400 to the load lock chamber 122. More specifically, the controller 500 controls the first on-off valve 414 to supply the N₂ gas from the tank 400 to the load lock chamber 122.

Note that the processed substrate 200 transferred from the process chamber 202 is heated to a processing temperature by the processing of forming a film, and thus, has a higher temperature than the N₂ gas supplied from the tank 400 to the load lock chamber 122. In other words, in step S204, the processed substrate 200 is cooled by the N₂ gas supplied from the tank 400 to the load lock chamber 122. Then, the controller 500 proceeds to step S206.

Next, in step S206, the controller 500 moves the N₂ gas in the load lock chamber 122 from the load lock chamber 122 to the accumulator 402. More specifically, the controller 500 controls the second three-way valve 432 to connect the discharge pipe 430 and the second introduction pipe 436, and controls the third three-way valve 434 to connect the bypass pipe 440 and the exhaust pipe 442. Note that, since the N₂ gas is supplied from the tank 400 to the load lock chamber 122 through the supply pipe 410 and the pressure in the load lock chamber 122 exceeds that in the accumulator 402, the N₂ gas heated by cooling of the processed substrate in the load lock chamber 122 flows to the accumulator 402. Then, the controller 500 proceeds to step S208.

Next, in step S208, the controller 500 determines whether a temperature of the processed substrate 200 is equal to or higher than a predetermined temperature (threshold). Then, if an affirmative determination is made in step S208, the controller 500 proceeds to step S210. On the other hand, if a negative determination is made in step S208, the controller 500 proceeds to step S214.

Next, in step S210, the controller 500 determines whether the accumulator 402 is fully filled with the N₂ gas heated by cooling of the processed substrate stored in the accumulator 402. Then, if an affirmative determination is made in step S210, the controller 500 proceeds to step S212. On the other hand, if a negative determination is made in step S210, the controller 500 proceeds to step S208.

Next, in step S212, the controller 500 switches the destination of the N₂ gas to the discharger. More specifically, the controller 500 controls the second three-way valve 432 to connect the discharge pipe 430 and the bypass pipe 440, and controls the third on-off valve 446 to open the third on-off valve 446. In addition, the controller 500 controls the vacuum pump 406 to discharge the N₂ gas from the load lock chamber 122 to an atmospheric space through the exhaust pipe 442. Then, the controller 500 proceeds to step S208. That is, when the inside of the accumulator 402 is filled with the heated N₂ gas, supply of N₂ to the accumulator 402 is stopped, and the heated N₂ is discharged to the discharger.

That is, in the present embodiment, the controller 500 cools the processed substrate 200 with a N₂ gas by steps S208 to S212.

Next, in step S214, the controller 500 stops supply of the N₂ gas from the tank 400 to the load lock chamber 122. More specifically, the controller 500 controls the first on-off valve 414 to close the first on-off valve 414, thereby stopping a flow of the N₂ gas supplied from the tank 400.

### Step of transferring processed substrate to atmospheric transfer chamber and storing processed substrate in pod

Subsequently, in a step of transferring the processed substrate 200 to the atmospheric transfer chamber 121 and storing the processed substrate 200 in the pod 100, the controller 500 opens the gate valve 128 of the load lock chamber 122 after returning the pressure in the load lock chamber to the atmospheric pressure, and operates the atmospheric transfer robot 124 to transfer the processed substrate 200 to the atmospheric transfer chamber 121. In addition, the atmospheric transfer robot 124 stores the processed substrate 200 in the pod 100 mounted on the IO stage 105.

In the method of manufacturing a semiconductor device in the present embodiment, the first substrate 200 is processed by the above steps using the substrate processing apparatus 10. Note that, in the method of manufacturing a semiconductor device according to the present embodiment, a processing step for the second substrate 200 may be partially different from the processing procedure for the first unprocessed substrate 200.

### Processing step for second and subsequent substrates

Specifically, in a case where the second unprocessed substrate 200 is processed, the first processed substrate 200 is cooled and the heated inert gas is accumulated in the accumulator 402, and therefore a negative determination is not made in step S106 in FIG. 7 in some cases. That is, in a case where the second unprocessed substrate 200 is processed, at a time when the unprocessed substrate 200 is transferred to the load lock chamber 122 (before step S102), a high-temperature inert gas is stored in the accumulator 402, and thus heating of the inert gas is not required in some cases.

In other words, in a case where the unprocessed substrate 200 is the second or subsequent substrate, the controller 500 supplies the inert gas accumulated in the accumulator 402 and heated by cooling the first processed substrate 200 to the second unprocessed substrate 200 to heat the second unprocessed substrate 200.

The other steps are similar to those for the processing for the first substrate 200.

Note that the substrate processing apparatus 10 in the present embodiment includes the plurality of (four in FIG. 1) process chambers 202 and the plurality of (two in FIG. 1) load lock chambers 122 as illustrated in FIG. 1, and thus also includes two accumulators 402. Therefore, in a case where the heated inert gas is not accumulated in the accumulator 402 at a time when the unprocessed substrate 200 is loaded into the load lock chamber 122, such as in a case where the next substrate 200 is loaded thereinto during processing of the unprocessed substrate 200, a procedure for the second unprocessed substrate 200 is similar to that for the first substrate.

According to the above procedure, in the method of manufacturing a semiconductor device in the present embodiment, the processed substrate 200 is cooled by the inert gas supplied to the load lock chamber 122. In other words, the inert gas supplied from the tank 400 without passing through the accumulator 402 is an example of a cooling fluid in the present embodiment. In other words, it can be said that the inert gas supplied from the tank 400 without passing through the accumulator 402 is supplied from the first supplier. That is, the inert gas supplied from the first supplier is an example of a fluid for cooling the heated substrate 200.

In other words, it can be said that the configuration of supplying the inert gas to the substrate mounting table 150 in the load lock chamber 122 is an example of a cooler configured in the substrate mounting table 150. That is, it can be said that the load lock chamber 122 in the present embodiment cools the processed substrate 200 by the cooler configured in the substrate mounting table 150.

The substrate mounting table 150 of the load lock chamber 122 includes a cooler that cools the substrate, and the cooler included in the substrate mounting table 150 cools the substrate. Note that the cooler has a configuration in which a fluid for cooling the substrate flows, and an inert gas may be used as the fluid. In other words, it can be said that the configuration of supplying the inert gas to the substrate mounting table 150 in the load lock chamber 122 is an example of the cooler configured in the substrate mounting table 150. The inert gas supplied to the load lock chamber 122 and the cooler configured in the substrate mounting table 150 may cool the substrate.

The controller 500 according to the present embodiment stores the inert gas in the load lock chamber 122 in the accumulator 402 through the process controller 522. More specifically, by controlling the second three-way valve 432 to connect the discharge pipe 430 and the second introduction pipe 436 and controlling the third three-way valve 434 to connect the bypass pipe 440 and the exhaust pipe 442, the inert gas in the load lock chamber 122 is stored in the accumulator 402.

As described above, since the processed substrate 200 has a higher temperature than the inert gas supplied to the load lock chamber 122, the inert gas supplied to the load lock chamber 122 is heated by the processed substrate 200. Therefore, the inert gas stored in the accumulator 402 has a higher temperature than the inert gas supplied from the tank 400. In other words, the inert gas stored in the accumulator 402 is an example of the fluid heated by cooling the heated processed substrate 200 in the present embodiment.

In a case where processing of forming a thin film on the substrate 200 is performed using the substrate processing apparatus 10 according to the present embodiment, the substrate 200 is transferred from the pod 100 to the load lock chamber 122 through the atmospheric transfer chamber 121, and is mounted on the substrate mounting table 150. Note that the unprocessed substrate 200 mounted on the substrate mounting table 150 of the load lock chamber 122 is outside the process chamber 202, that is, at room temperature.

Here, the controller 500 according to the present embodiment supplies an inert gas from the supply pipe 410 to the unprocessed substrate 200 mounted on the substrate mounting table 150 through the process controller 522, thereby supplying the inert gas to the processed substrate 200 at room temperature. More specifically, the controller 500 controls the first three-way valve 416 to connect an upstream side of the supply pipe 410 and the first introduction pipe 420 side, and controls the second on-off valve 418 to open the first discharge pipe 422. As a result, the controller 500 causes the inert gas supplied from the tank 400 to flow into the load lock chamber 122 via the accumulator 402.

Here, since the inert gas having a high temperature is accumulated in the accumulator 402 by performing the cooling operation on the processed substrate 200 as described above, the inert gas supplied to the load lock chamber 122 also has a high temperature. In other words, the inert gas supplied via the accumulator 402 is an example of the fluid for heating a space in the load lock chamber 122 in the present embodiment. In other words, it can be said that the inert gas supplied via the accumulator 402 is supplied from the second supplier. That is, the inert gas supplied from the second supplier is an example of the fluid for heating the unprocessed substrate 200 that has not been heated.

The controller 500 according to the present embodiment discharges the inert gas in the load lock chamber 122 to an atmospheric space through the process controller 522. More specifically, by controlling the second three-way valve 432 to connect the discharge pipe 430 and the bypass pipe 440 and controlling the third three-way valve 434 to connect the bypass pipe 440 and the exhaust pipe 442, the inert gas in the load lock chamber 122 is caused to flow through the exhaust pipe 442. The controller 500 controls the third on-off valve 446 to open the exhaust pipe 442 to the outside, and causes the vacuum pump 406 to be operated to send the fluid in the exhaust pipe 442 to a downstream side to discharge the fluid to the atmospheric space.

As described above, in a case where the substrate 200 loaded into the load lock chamber 122 is the processed substrate 200, the controller 500 according to the present embodiment supplies an inert gas from the first supplier in order to cool the substrate 200. In a case where the substrate 200 loaded into the load lock chamber 122 is the unprocessed substrate 200, the controller 500 according to the present embodiment supplies an inert gas from the second supplier in order to heat the substrate 200. In other words, the controller 500 according to the present embodiment switches to the first supplier or the second supplier depending on a status of the substrate 200 loaded into the load lock chamber 122.

Note that, in a case where a temperature of an inert gas in the accumulator 402 is lower than a predetermined temperature in preheating operation, the controller 500 may cause the heater 404 to be operated to heat the inert gas in the accumulator 402.

According to the present embodiments, one or more effects described below are exhibited.

### Operations and Effects

According to the substrate processing apparatus 10 in the present embodiment, by accumulating a fluid heated by cooling the processed substrate 200 mounted in the load lock chamber 122 in the accumulator 402, supplying the accumulated fluid to the load lock chamber 122, and using the fluid for heating the unprocessed substrate 200 mounted in the load lock chamber 122, the amount of fluid used can be reduced. In addition, according to the substrate processing apparatus 10 in the present embodiment, heating the unprocessed substrate 200 in advance can contribute to shortening a heating time of the substrate 200 in the process chamber 202 and reducing the amount of power used for heating the substrate 200. In addition, according to the substrate processing apparatus 10 in the present embodiment, shortening the heating time of the substrate 200 can contribute to improvement of productivity.

In addition, according to the substrate processing apparatus 10 in the present embodiment, by using an inert gas as a fluid that cools the processed substrate 200 or heats the unprocessed substrate 200, an influence on a surface of the substrate 200 can be suppressed.

In addition, according to the substrate processing apparatus 10 in the present embodiment, by heating the unprocessed substrate 200 using a heated and held fluid accumulated in the accumulator 402, the amount of fluid used can be reduced. In addition, by heating the unprocessed substrate 200 in advance in the load lock chamber 122, a heating time of the substrate 200 when the substrate 200 is processed in the process chamber 202 can be shortened, which can contribute to improvement of productivity.

In addition, according to the substrate processing apparatus 10 in the present embodiment, by switching a discharge destination switching valve, a fluid that is not heated can be discharged to the atmospheric space, and a heated fluid can be caused to flow into the accumulator 402.

In addition, according to the substrate processing apparatus 10 in the present embodiment, by switching a supply source switching valve, a heated fluid can be caused to flow from the accumulator 402 into the load lock chamber 122 to heat the unprocessed substrate 200, or a cooled fluid can be caused to flow from the tank 400 to the load lock chamber 122 through the supply pipe 410 to cool the processed substrate 200.

In addition, according to the substrate processing apparatus 10 in the present embodiment, by cooling the inside of the load lock chamber 122, an influence of heating on each member in the load lock chamber 122 can be suppressed.

In addition, according to the substrate processing apparatus 10 in the present embodiment, use of the cooler included in the substrate mounting table 150 together with a cooling fluid can contribute to reduction of a cooling time of the heated processed substrate 200.

In addition, according to the substrate processing apparatus 10 in the present embodiment, by cooling the substrate 200 heated by a fluid, an influence on a surface of the substrate 200 can be suppressed.

In addition, according to the substrate processing apparatus 10 in the present embodiment, by heating the inside of the load lock chamber 122 using a fluid accumulated in the accumulator 402, the amount of fluid used can be reduced.

In addition, according to the substrate processing apparatus 10 in the present embodiment, by heating the unprocessed substrate 200 using a fluid accumulated in the accumulator 402, the amount of fluid used can be reduced.

In addition, according to the substrate processing apparatus 10 in the present embodiment, by measuring a temperature in the load lock chamber 122, the supply amount of a heated fluid into the load lock chamber 122 can be controlled.

In addition, according to the substrate processing apparatus 10 in the present embodiment, the supply amount of a heated fluid into the load lock chamber 122 can be controlled by measuring a pressure in the load lock chamber 122.

In addition, according to the substrate processing apparatus 10 in the present embodiment, a worker can check a status of a fluid supplied to the load lock chamber 122.

In addition, the substrate processing apparatus 10 in the present embodiment further includes the heater 404 that heats a fluid that is caused to flow from the substrate 200 to the container. As a result, a temperature of the fluid flowing from the accumulator 402 to the container can be set to a desired value, and therefore a quality of the substrate processing step can be improved.

The method of manufacturing a semiconductor device according to the present embodiment includes: a step of heating the substrate 200 in the process chamber 202; a step of mounting the processed substrate 200 unloaded from the process chamber 202 in a container; a step of cooling the processed substrate 200 mounted in the container with a fluid supplied from a supplier; a step of accumulating the fluid heated by cooling the processed substrate 200 in the accumulator 402; and a step of supplying the fluid accumulated in the accumulator 402 to the unprocessed substrate 200 stored in the process chamber 202 to heat the unprocessed substrate 200.

The method of manufacturing a semiconductor device according to the present embodiment can shorten a heating time of the substrate 200 in the process chamber 202 to improve productivity by heating the unprocessed substrate in the load lock chamber 122 in advance.

A program according to the present embodiment causes the controller 500 to execute: a procedure of heating the substrate 200 in the process chamber 202; a procedure of mounting the processed substrate 200 unloaded from the process chamber 202 in a container; a procedure of cooling the processed substrate 200 mounted in the container with a fluid supplied from a supplier; a procedure of accumulating the fluid heated by cooling the processed substrate 200 in the accumulator 402; and a procedure of supplying the fluid accumulated in the accumulator 402 to the unprocessed substrate 200 stored in the process chamber 202 to heat the unprocessed substrate 200.

The program according to the present embodiment can shorten a heating time of the substrate 200 in the process chamber 202 to improve productivity by heating the unprocessed substrate in the load lock chamber 122 in advance.

In addition, in the above description, the fluid supplied from the tank 400 to the load lock chamber 122 is an inert gas, but the technique according to the present disclosure is not limited thereto. For example, a process gas or compressed air may be supplied instead of the inert gas.

In addition, in the above description, the accumulator 402 includes the housing 407 surrounded by the heat insulating member 408, but the technique according to the present disclosure is not limited thereto. For example, the accumulator 402 does not have to include the heat insulating member 408.

In addition, in the above description, the inert gas discharge system 344 includes the discharge pipe 430, the second three-way valve 432, and the third three-way valve 434, but the technique according to the present disclosure is not limited thereto. For example, the inert gas discharge system 344 does not have to include the second three-way valve 432 or the third three-way valve 434, and may include piping through which a fluid flows directly from the load lock chamber 122 to the accumulator 402 and piping through which the fluid is discharged directly from the load lock chamber 122.

In addition, in the above description, the substrate 200 mounted on the substrate mounting table 150 in the load lock chamber 122 is heated or cooled by supplying a fluid into the load lock chamber 122, but the technique according to the present disclosure is not limited thereto. For example, the fluid may heat or cool the substrate 200 from the outside of the load lock chamber 122 via a heat conduction member.

In addition, in the above description, the substrate processing apparatus 10 includes the temperature sensor 302 in the load lock chamber 122, but the technique according to the present disclosure is not limited thereto. For example, the substrate processing apparatus 10 does not have to include the temperature sensor 302 in the load lock chamber 122, and the controller 500 may control a flow rate of a fluid on the basis of an elapse of a predetermined time.

In addition, in the above description, the substrate processing apparatus 10 includes the pressure sensor 304 in the load lock chamber 122, but the technique according to the present disclosure is not limited thereto. For example, the substrate processing apparatus 10 does not have to include the pressure sensor 304 in the load lock chamber 122, and the controller 500 may control a flow rate of a fluid on the basis of an elapse of a predetermined time.

In addition, in the above description, each configuration of the substrate processing apparatus 10 is schematically displayed on the display 518, but the technique according to the present disclosure is not limited thereto. For example, the display 518 does not have to have a screen display, and a transfer mechanism may be indicated by turning on and off a lamp. In addition, for example, the substrate processing apparatus 10 does not have to include the display 518.

In addition, in the above description, the heater 404 is disposed in the accumulator 402, but the technique according to the present disclosure is not limited thereto. For example, the heater 404 may be disposed in the first introduction pipe 420, the second introduction pipe 436, or the first discharge pipe 422 to heat a fluid flowing through the piping. The heater 404 may be disposed on a downstream side of a connector of the supply pipe 410 to the first discharge pipe 422 to heat a fluid flowing through the supply pipe 410.

In addition, in the above description, a program is stored in the memory, but a program providing method according to the present disclosure is not limited thereto. For example, the program may be recorded in a computer-readable recording medium and provided together with the recording medium.

Also in these modified examples, productivity can be improved by shortening a heating time of the substrate 200.

The above-described aspect has described an example in which a film is formed using the single wafer type substrate processing apparatus 10 that processes one or several substrates 200 at a time. The present disclosure is not limited to the above-described aspect. For example, the present disclosure is suitably applicable to a case where a film is formed using the batch type substrate processing apparatus 10 that processes a plurality of substrates 200 at a time. The above-described aspect has also described an example in which a film is formed using the substrate processing apparatus 10 including a cold wall type processing furnace. The present disclosure is not limited to the above-described aspect. For example, the present disclosure is suitably applicable to a case where a film is formed using the substrate processing apparatus 10 including a hot wall type processing furnace.

Also in these cases where the substrate processing apparatus 10 is used, each piece of processing can be performed according to processing procedures and processing conditions similar to those in the above-described aspect and modified examples, and effects similar to those in the above-described aspect and modified examples can be obtained.

### Other modified examples

The embodiments of the present disclosure have been specifically described above, but the present disclosure is not limited to the above-described embodiments, and various modifications can be made without departing from the gist of the present disclosure.

In addition, for example, in each of the above-described embodiments, the film forming processing has been described as an example of the processing performed by the substrate processing apparatus, but the present disclosure is not limited thereto. That is, the present disclosure can also be applied to film forming processing other than the thin film forming processing exemplified in each of the embodiments in addition to the film forming processing exemplified in each of the embodiments. In addition, the specific content of the substrate processing may be any content, and the present disclosure can be applied not only to the film forming processing but also to other types of substrate processing such as annealing processing, diffusing processing, oxidizing processing, and nitriding processing. Furthermore, the present disclosure can also be applied to, for example, other substrate processing apparatuses such as an annealing processing apparatus, an etching apparatus, an oxidizing processing apparatus, a nitriding processing apparatus, an exposure apparatus, a coating apparatus, a drying apparatus, a heating apparatus, and a processing apparatus using plasma. In addition, in the present disclosure, these apparatuses may be mixed. In addition, a part of a configuration of one embodiment can be replaced with a configuration of another embodiment, and a configuration of one embodiment can be added to a configuration of another embodiment. To a part of a configuration of each of the embodiments, another configuration can be added, a part of a configuration of each of the embodiments can be deleted, or a part of a configuration of each of the embodiments can be replaced with another configuration.

According to the present disclosure, productivity can be improved by shortening a heating time of a substrate.

What is claimed is:

1. A substrate processing apparatus comprising:
a process chamber in which a substrate is heated;
a container in which an unprocessed substrate to be loaded into the process chamber or a processed substrate unloaded from the process chamber is mounted;
a supplier that supplies a fluid for heating the unprocessed substrate mounted in the container or cooling the processed substrate;
a discharger that discharges the fluid from the container;
an accumulator in which the fluid heated by cooling the processed substrate is accumulated; and
a controller capable of performing control to supply the fluid accumulated in the accumulator to the container to heat the unprocessed substrate.

2. The substrate processing apparatus according to claim 1, wherein:
the fluid is an inert gas.

3. The substrate processing apparatus according to claim 1, wherein:
the accumulator includes a heat insulating material that maintains a temperature of the heated fluid.

4. The substrate processing apparatus according to claim 1, wherein:
the discharger includes a discharge pipe and a discharge destination switching valve, and
the controller controls the accumulation of fluid in the accumulator through the discharge pipe by switching the discharge destination switching valve.

5. The substrate processing apparatus according to claim 4, wherein:
the controller controls supply of cooling fluid from the supplier and stores the fluid heated by cooling the heated processed substrate in the accumulator by switching the discharge destination switching valve when the heated processed substrate is loaded into the container.

6. The substrate processing apparatus according to claim 4, wherein:
the controller controls discharge of the fluid in the container from the discharger to an atmospheric space by switching the discharge destination switching valve when the unprocessed substrate is loaded into the container.

7. The substrate processing apparatus according to claim 1, wherein:
the supplier includes a supply pipe connected to a supply source of a fluid and a supply source switching valve, and
the controller controls supply of the heated fluid from the accumulator to the container through the supply pipe or to cause a cold fluid to flow from the fluid supply source to the container through the supply pipe by switching the supply source switching valve.

8. The substrate processing apparatus according to claim 7, wherein the supplier includes a first supplier that supplies the cooled fluid, and the controller controls supply of the fluid from the supplier by switching a supply source switching valve of the first supplier when the heated processed substrate is loaded into the container.

9. The substrate processing apparatus according to claim 7, wherein the supplier includes a second supplier that supplies the heated fluid, and the controller controls supply of the fluid from the accumulator by switching a supply source switching valve of the second supplier when the unprocessed substrate is loaded into the container.

10. The substrate processing apparatus according to claim 1, wherein:
the supplier includes a first supplier that supplies the fluid for cooling the substrate and a second supplier that supplies the fluid for heating the substrate, and
the controller switches to the first supplier or the second supplier depending on a status of the substrate loaded into the container.

11. The substrate processing apparatus according to claim 10, wherein:
the container includes a substrate mounting table on which a substrate is mounted, and
a cooler configured on the substrate mounting table and the fluid for cooling the substrate cool the heated processed substrate.

12. The substrate processing apparatus according to claim 10, wherein:
the fluid supplied from the first supplier is a fluid for cooling the heated processed substrate.

13. The substrate processing apparatus according to claim 10, wherein:
the fluid supplied from the second supplier is a fluid for heating a space in the container.

14. The substrate processing apparatus according to claim 10, wherein:
the fluid supplied from the second supplier is a fluid for heating the unheated unprocessed substrate.

15. The substrate processing apparatus according to claim 1, comprising a temperature sensor that measures a temperature in the container, wherein:
the controller controls a flow rate of the fluid according to a temperature measured by the temperature sensor.

16. The substrate processing apparatus according to claim 1, comprising a pressure sensor that measures a pressure in the container, wherein:
the controller controls a flow rate of the fluid according to a pressure measured by the pressure sensor.

17. The substrate processing apparatus according to claim 1, further comprising a heater that heats the fluid supplied from the accumulator to the container.

18. A substrate processing method comprising:
heating a substrate in a process chamber;
mounting the processed substrate unloaded from the process chamber in a container;
cooling the processed substrate mounted in the container with a fluid supplied from a supplier;
cooling the processed substrate to accumulate the heated fluid in the accumulator; and
supplying the fluid accumulated in the accumulator to the unprocessed substrate stored in the container to heat the unprocessed substrate.

19. A method of manufacturing a semiconductor device, the method comprising the substrate processing method according to claim 18.

20. A non-transitory computer-readable recording medium recording a program that causes, by a computer, a substrate processing apparatus to execute:
heating a substrate in a process chamber;
mounting the processed substrate unloaded from the process chamber in a container;
cooling the processed substrate mounted in the container with a fluid supplied from a supplier;
cooling the processed substrate to accumulate the heated fluid in the accumulator; and
supplying the fluid accumulated in the accumulator to the unprocessed substrate stored in the container to heat the unprocessed substrate.
